(19) United States
(12) Patent Application Publication
(10) Pub. No.: US 2025/0022873 A1
(43) Pub. Date: Jan. 16, 2025

(54) SEMICONDUCTOR DEVICE

(71) Applicant: Murata Manufacturing Co., Ltd., Kyoto-fu (JP)

(72) Inventors: Masayuki AOIKE, Nagaokakyo-shi (JP); Shinnosuke TAKAHASHI, Nagaokakyo-shi (JP); Masatoshi HASE, Nagaokakyo-shi (JP); Fumio HARIMA, Nagaokakyo-shi (JP)

(73) Assignee: Murata Manufacturing Co., Ltd., Kyoto-fu (JP)

(21) Appl. No.: 18/901,620

(22) Filed: Sep. 30, 2024

Related U.S. Application Data
(63) Continuation of application No. PCT/JP2023/016309, filed on Apr. 25, 2023.

(30) Foreign Application Priority Data
Apr. 27, 2022 (JP) 2022-073413

(51) Int. Cl. H01L 27/06; H01L 23/00; H01L 23/14; H01L 23/373; H01L 23/528; H01L 29/205; H01L 29/737

(52) U.S. Cl. CPC H01L 27/0652; H01L 23/147; H01L 23/528; H01L 24/29; H01L 24/32; H01L 29/7371; H01L 23/3738; H01L 29/205; H01L 2224/29124; H01L 2224/29139; H01L 2224/29144; H01L 2224/29147; H01L 2224/29166; H01L 2224/29169; H01L 2224/29184; H01L 2224/32225

(57) ABSTRACT

A bonding layer including a first metal region is disposed on at least a portion of an upper surface of a support substrate. An underlying layer including a sub-collector region that is made of a conductive semiconductor material and is electrically connected to the first metal region is disposed on the bonding layer. A first transistor including a collector layer electrically connected to the sub-collector region, a base layer disposed on the collector layer, and an emitter layer disposed on the base layer is disposed on the sub-collector region. On the sub-collector region, a collector electrode electrically connected to the sub-collector region is located outward of the first transistor to overlap the first metal region in plan view.

### CROSS-REFERENCE TO RELATED APPLICATIONS

This application claims benefit of priority to International Patent Application No. PCT/JP2023/016309, filed Apr. 25, 2023, and to Japanese Patent Application No. 2022-073413, filed Apr. 27, 2022, the entire contents of each are incorporated herein by reference.

### BACKGROUND

### Technical Field

The present disclosure relates to a semiconductor device.

### Background Art

A semiconductor device in which a semi-insulating GaAs substrate is joined onto a Si substrate via a junction layer, such as an Au film, is known as described, for example, in Japanese Unexamined Patent Application Publication No. 2021-2644. An n-type sub-collector layer is disposed on the semi-insulating GaAs substrate, and a heterojunction bipolar transistor (HBT) is disposed thereon. A collector electrode in addition to the HBT is disposed on the n-type sub-collector layer. The collector electrode is connected to the collector layer of the HBT via the n-type sub-collector layer.

### SUMMARY

In the conventional semiconductor device, the collector electrode is connected to the collector layer via the sub-collector layer. A semiconductor layer doped with a high-concentration n-type dopant for reduction in resistance is used as the n-type sub-collector layer, but the resistance is higher than that of metal, and the parasitic resistance that occurs between the collector electrode and the collector layer prevents the operating speed of the transistor from being increased.

Accordingly, the present disclosure provides a semiconductor device in which the parasitic resistance between the collector electrode and the collector layer is reduced to increase the operating speed of a transistor.

According to an aspect of the present disclosure, there is provided a semiconductor device including a support substrate; a bonding layer including a first metal region disposed on at least a portion of an upper surface of the support substrate; an underlying layer disposed on the bonding layer, the underlying layer including a sub-collector region made of a conductive semiconductor material and electrically connected to the first metal region; a first transistor disposed on the sub-collector region, the first transistor including a collector layer electrically connected to the sub-collector region, a base layer disposed on the collector layer, and an emitter layer disposed on the base layer; and a collector electrode disposed on the sub-collector region. The collector electrode is located outward of the first transistor to overlap the first metal region in plan view, and the collector electrode is electrically connected to the sub-collector region.

The parasitic resistance between the collector layer and the collector electrode of the first transistor is reduced because the first metal region is connected to the sub-collector region. As a result, the operating speed of the first transistor can be increased.

### BRIEF DESCRIPTION OF THE DRAWINGS

FIG. 1 is a schematic plan view of a semiconductor device according to a first example;

FIG. 2 is a cross-sectional view taken along dashed line 2-2 in FIG. 1;

FIGS. 3A to 3F are schematic cross-sectional views of the semiconductor device at mid-production stages;

FIGS. 4A, 4B, and 4C are schematic cross-sectional views of the semiconductor device at mid-production stages, and FIG. 4D is a schematic cross-sectional view of the completed semiconductor device;

FIG. 5 is a schematic diagram of a first transistor of the semiconductor device according to the first example;

FIG. 6 is a cross-sectional view of a semiconductor device according to a second example;

FIGS. 7A, 7B, and 7C are cross-sectional views of the semiconductor device according to the second example at mid-production stages;

FIG. 8 is a diagram schematically illustrating a cross-sectional structure of a semiconductor device according to a third example;

FIG. 9 is a diagram schematically illustrating a cross-sectional structure of the semiconductor device according to the third example;

FIG. 10 is a diagram schematically illustrating a cross-sectional structure of a semiconductor device according to a fourth example;

FIG. 11 is a diagram schematically illustrating a cross-sectional structure of a semiconductor device according to a fifth example;

FIG. 12 is an equivalent circuit diagram of a semiconductor device according to a sixth example; and

FIG. 13 is a diagram schematically illustrating a cross-sectional structure of the semiconductor device according to the sixth example.

### DETAILED DESCRIPTION

### First Example

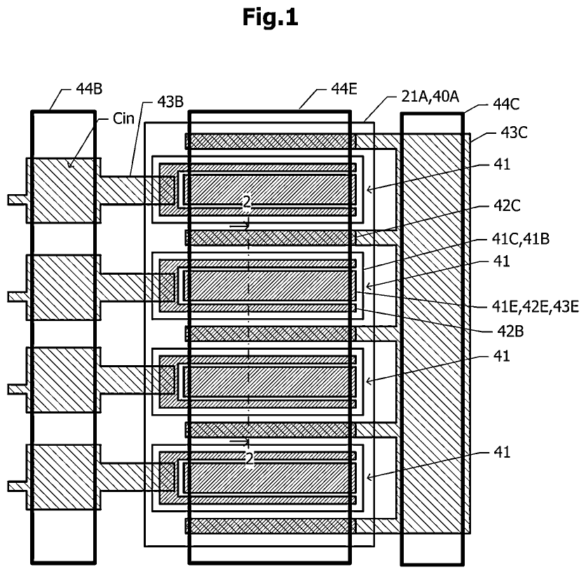

A semiconductor device according to a first example will be described with reference to FIGS. 1 to 5.

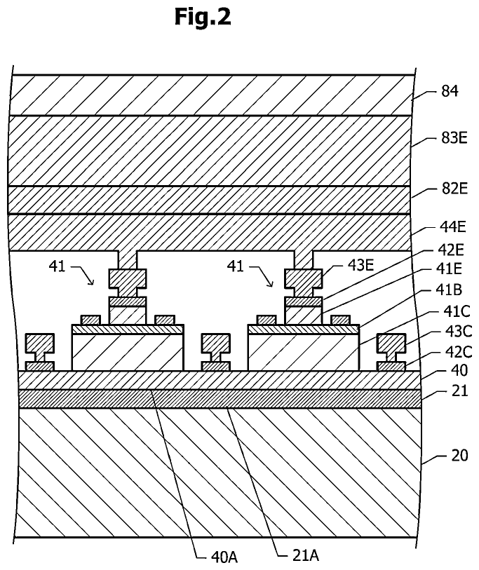

FIG. 1 is a schematic plan view of the semiconductor device according to the first example. A bonding layer 21 including a metal region 21A is disposed on a support substrate 20, which will be described later with reference to FIG. 2. A sub-collector region 40A made of a semiconductor material is disposed to almost overlap the metal region 21A. A plurality of first transistors 41 are disposed in, for example, one direction (an up-down direction in FIG. 1) on this sub-collector region 40A.

Each of the first transistors 41 includes a collector layer 41C, a base layer 41B, and an emitter layer 41E. The collector layer 41C and the base layer 41B almost overlap each other in plan view. The emitter layer 41E is smaller than the base layer 41B and is contained in the base layer 41B in plan view.

Emitter electrodes 42E are disposed to almost overlap the emitter layer 41E in plan view. In plan view, the emitter electrodes 42E are longer in a direction (left-right direction in FIG. 1) orthogonal to the direction in which the first transistors 41 are arranged. The shape of the emitter electrodes 42E in plan view is, for example, a rectangle. In plan view, a U-shaped base electrode 42B is disposed so as to be spaced apart from two long sides and one short side of each of the emitter electrodes 42E. The base electrodes 42B are open in the same direction (in the right direction in FIG. 1).

A collector electrode 42C is disposed between two adjacent first transistors 41 and on the outer side of each of the first transistors 41 at both ends. In FIG. 1, the collector electrodes 42C, the emitter electrodes 42E, and the base electrodes 42B are marked with relatively dense upward-right hatching.

Each of base lines 43B of the first layer is connected to a portion of each of the plurality of base electrodes 42B spaced apart from the short side of the emitter electrode 42E. The base lines 43B extend to the outside of the sub-collector region 40A in a direction away from the emitter electrodes 42E. The base lines 43B intersect a common base line 44B of the second layer in plan view. Input capacitors Cin are formed at intersections between the base lines 43B of the first layer and the base line 44B of the second layer. A high-frequency signal from the base line 44B of the second layer is input to the base electrodes 42B through the input capacitors Cin and the base lines 43B of the first layer.

A collector line 43C of the first layer is connected to the plurality of collector electrodes 42C. The collector line 43C extends, in a direction opposite to the direction in which the base lines 43B extend, from positions at which the collector line 43C overlaps the collector electrodes 42C and are connected to each other outside the sub-collector region 40A. In FIG. 1, the base lines 43B and the collector line 43C are marked with relatively light downward-right hatching. Emitter lines 43E of the first layer are disposed to almost overlap the emitter electrodes 42E.

An emitter line 44E of the second layer is disposed so as to overlap all of the emitter lines 43E from the emitter line 43E at one end to the emitter line 43E at the other end in the direction in which the first transistors 41 are arranged. The emitter line 44E of the second layer connects the plurality of emitter lines 43E of the first layer to each other. As described above, the emitters of the plurality of first transistors 41 are connected to each other, and collectors are connected to each other, and accordingly, the plurality of first transistors 41 are connected to each other in parallel. A collector line 44C of the second layer is disposed so as to overlap the collector line 43C outside the sub-collector region 40A. In FIG. 1, the emitter line 44E, the collector line 44C, and the base line 44B of the second layer are represented by relatively thick outlines.

FIG. 2 is a cross-sectional view taken along dashed line 2-2 in FIG. 1. The bonding layer 21 is disposed on the support substrate 20. The bonding layer 21 includes at least one metal region 21A. FIG. 2 illustrates a cross section of one metal region 21A of the bonding layer 21. For example, a high-resistance silicon substrate can be used as the support substrate 20. For example, an Au film can be used as the bonding layer 21. It should be noted that a metal film including Ag, Pt, Cu, Al, W, Ti, or Ta besides Au may also be used. In other words, the bonding layer 21 includes at least one metal selected from the group consisting of Au, Ag, Pt, Cu, Al, W, Ti, and Ta.

An underlying layer 40 made of a semiconductor material is joined onto the bonding layer 21. The underlying layer 40 includes a conductive sub-collector region 40A and an insulating element isolation region. FIG. 2 illustrates a cross section of the sub-collector region 40A, but does not illustrate the element isolation region. The plurality of first transistors 41 are disposed on the sub-collector region 40A.

Each of the first transistor 41 includes the collector layer 41C, the base layer 41B, and the emitter layer 41E laminated in sequence on the underlying layer 40. The first transistor 41 is, for example, a heterojunction bipolar transistor. As an example, the sub-collector region 40A of the underlying layer 40 and the collector layer 41C are formed of n-type GaAs, and the base layer 41B is formed of p-type GaAs. The emitter layer 41E includes two layers: for example, an n-type InGaP layer and an n-type GaAs layer thereon. It should be noted that these semiconductor layers may also be formed of other compound semiconductors, such as InP, GaN, SiGe, SiC, or the like.

The plurality of collector electrodes 42C are disposed on the sub-collector region 40A to interpose each of the first transistors 41 therebetween. It should be noted that one collector electrode 42C is disposed between two adjacent first transistors 41, and one collector electrode 42C is shared by the first transistors 41 on both sides.

The collector electrode 42C is electrically connected to the collector layer 41C via the sub-collector region 40A. In addition, the sub-collector region 40A is electrically connected to the metal region 21A thereunder. Here, the state in which the sub-collector region 40A is electrically connected to the metal region 21A includes the state in which both regions are in ohmic contact with each other and the state in which both regions are in Schottky contact with each other, but both regions are considered to be substantially in ohmic contact with each other because a Schottky barrier is sufficiently thin. For example, when the sub-collector region 40A is made of high-concentration n-type GaAs and both regions are in Schottky contact with each other, the Schottky barrier becomes sufficiently thin. On each of the collector electrodes 42C, the collector line 43C of the first layer is disposed via an interlayer insulating film (not illustrated). The collector line 43C is connected to the collector electrode 42C through a cavity provided in the interlayer insulating film.

The emitter layer 41E is disposed on a portion of the base layer 41B. It should be noted that a ledge structure in which the emitter layer 41E is disposed over the entire region of the base layer 41B and an emitter mesa is disposed on a portion of the emitter layer 41E may be adopted. In this structure, the region that overlaps the emitter mesa in plan view substantially serves as the emitter layer.

The base electrodes 42B are disposed on the base layer 41B, and the emitter electrodes 42E are disposed on the emitter layer 41E. The base electrodes 42B are electrically connected to the base layer 41B, and the emitter electrode 42E is electrically connected to the emitter layer 41E.

The emitter lines 43E of the first layer are disposed on the respective emitter electrodes 42E via an interlayer insulating film (not illustrated). The emitter lines 43E are electrically connected to the emitter electrodes 42E through cavities provided in the interlayer insulating film.

One emitter line 44E of the second layer is disposed on the plurality of emitter lines 43E of the first layer through the interlayer insulating film (not illustrated). The emitter line 44E of the second layer is connected to the plurality of emitter lines 43E of the first layer through a cavity provided in the interlayer insulating film. An emitter pad 82E is disposed on the emitter line 44E, and an emitter protrusion electrode 83E is disposed thereon. For example, a Cu pillar bump is used as the emitter protrusion electrode 83E. Solder 84 is placed on the emitter protrusion electrode 83E.

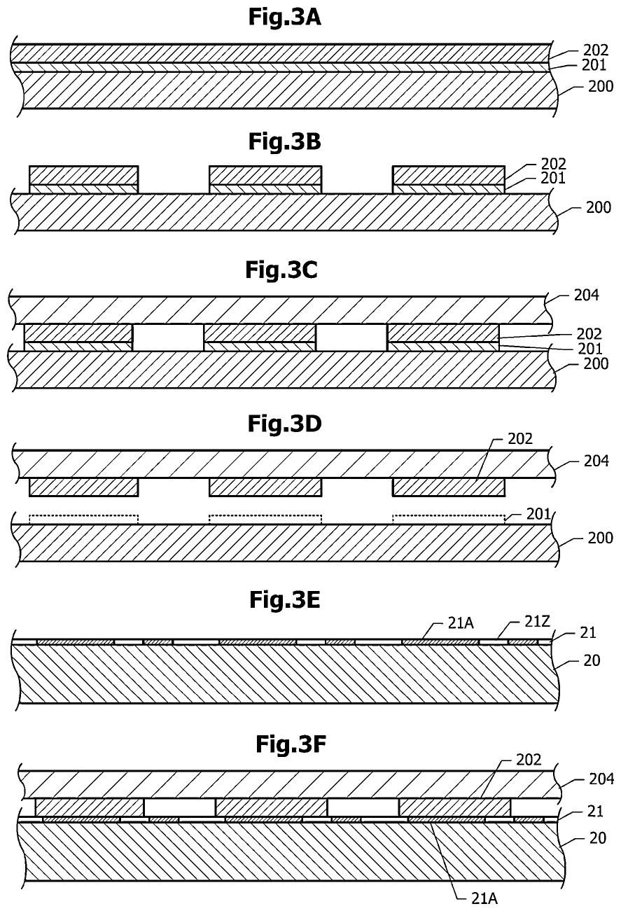

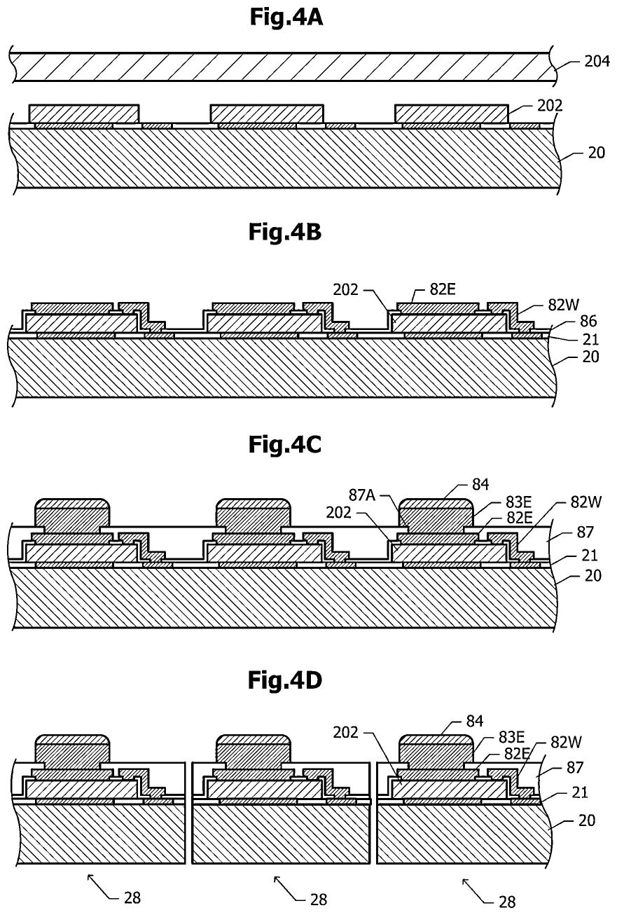

Next, a method of manufacturing of the semiconductor device according to the first example will be described with reference to FIGS. 3A to 4D. FIGS. 3A to 4C are schematic cross-sectional views of the semiconductor device at mid-production stages, and FIG. 4D is a schematic cross-sectional view of the completed semiconductor device.

As illustrated in FIG. 3A, an epitaxial growth of a peel layer 201 is caused on a mother substrate 200 of single-crystal compound semiconductor, such as GaAs, and an element forming layer 202 is formed on the peel layer 201. The element structure from the underlying layer 40 to the emitter line 44E of the second layer illustrated in FIG. 2 is formed in the element forming layer 202. This element structure is formed by a general semiconductor process. FIG. 3A does not illustrate the element structure formed in the element forming layer 202. At this stage, the element structures corresponding to a plurality of semiconductor devices are formed in the element forming layer 202, and the element structures are not separated into individual semiconductor devices. In addition, the emitter pad 82E, the emitter protrusion electrode 83E, and the solder 84 (FIG. 2) are not formed.

Next, as illustrated in FIG. 3B, the element forming layer 202 and the peel layer 201 are patterned by using a resist pattern (not illustrated) as an etching mask. At this stage, the element forming layer 202 is separated for each of the semiconductor devices.

Next, as illustrated in FIG. 3C, a coupling support body 204 is attached onto the separated element forming layers 202. As a result, the plurality of element forming layers 202 are connected to each other via the coupling support body 204. It should be noted that the resist pattern used as the etching mask in the patterning process in FIG. 3B may be saved, and the resist pattern may be interposed between the element forming layer 202 and the coupling support body 204.

Next, as illustrated in FIG. 3D, the peel layer 201 is selectively etched with respect to the mother substrate 200 and the element forming layer 202. As a result, the element forming layer 202 and the coupling support body 204 are peeled from the mother substrate 200. For selective etching of the peel layer 201, a compound semiconductor with different etching resistance from both the mother substrate 200 and the element forming layer 202 is used as the peel layer 201.

As illustrated in FIG. 3E, the bonding layer 21 is formed on the upper surface of the support substrate 20. The bonding layer 21 includes the plurality of metal regions 21A distributed in the surface and insulating regions 21Z disposed in regions in which the metal regions 21A are not disposed. The bonding layer 21 can be formed, for example, by a damascene process. The insulating regions 21Z are formed of, for example, an insulating oxide or nitride, specifically a silicon oxide, a silicon nitride, a silicon oxynitride, or the like.

As illustrated in FIG. 3F, the element forming layers 202 are joined to the bonding layer 21. The junction between the element forming layer 202 and the bonding layer 21 is achieved by van der Waals bonding or hydrogen bonding. Alternatively, the element forming layer 202 may be joined to the bonding layer 21 by an electrostatic force, covalent bonding, eutectic alloy bonding, or the like. For example, when the metal region 21A is made of Au, both layers may be joined to each other by pressing the element forming layer 202 against the Au film with both layers in close contact with each other.

Next, as illustrated in FIG. 4A, the coupling support body 204 is peeled from the element forming layer 202. After the coupling support body 204 is peeled, an interlayer insulating film 86 and a rewiring layer are formed on the bonding layer 21 and the element forming layer 202, as illustrated in FIG. 4B. The rewiring layer includes the emitter pad 82E disposed on the emitter line 44E (FIG. 2) and an interconnect line 82W that connects circuits included in the element forming layer 202 and one metal region of the bonding layer 21 to each other, and the like.

Next, as illustrated in FIG. 4C, a protective film 87 is formed on the rewiring layer including the emitter pad 82E, the interconnect line 82W, and the like, and a plurality of cavities 87A are formed in the protective film 87. The plurality of cavities 87A are contained in the plurality of emitter pads 82E, respectively, in plan view. The emitter protrusion electrode 83E is formed in each of the cavities 87A. It should be noted that the emitter protrusion electrode 83E extends to cover a portion of the protective film 87 around the cavity 87A. The emitter protrusion electrode 83E protrudes in a direction away from the support substrate 20. In addition, the solder 84 is placed on the top surface of the emitter protrusion electrode 83E, and reflow processing is performed.

Finally, as illustrated in FIG. 4D, the support substrate 20 is cut with a dicing machine. As a result, a diced semiconductor device 28 including the support substrate 20, the bonding layer 21, the element forming layer 202, the emitter pad 82E, the emitter protrusion electrode 83E, the interconnect lines 82W, and the like is obtained. In the diced semiconductor device 28, the support substrate 20 is larger than the element forming layer 202 in plan view. The diced semiconductor device is flip-chip mounted on a module substrate or the like.

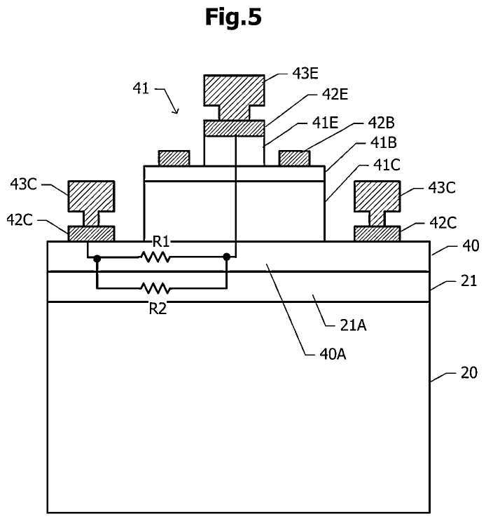

Next, excellent effects of the first example will be described with reference to FIG. 5. FIG. 5 is a schematic diagram of the first transistor 41 of the semiconductor device according to the first example. The collector electrode 42C is in contact with one surface of the sub-collector region 40A, and the metal region 21A is in contact with the other surface thereof. When the first transistor 41 operates, current flows from the collector electrode 42C in contact with one surface of the sub-collector region 40A to the emitter electrode 42E through the sub-collector region 40A, the collector layer 41C, the base layer 41B, and the emitter layer 41E. The parasitic resistance of the sub-collector region 40A is denoted as R1.

A resistance component R2 of the metal region 21A in contact with the other surface of the sub-collector region 40A is connected in parallel to the parasitic resistance R1 of the sub-collector region 40A. As a result, the parasitic resistance between the collector electrode 42C and the collector layer 41C is reduced. When the parasitic resistance is reduced, the operating frequency of the first transistor 41 can be increased. As described above, the bonding layer 21 has the function of reducing the parasitic resistance between the collector layer 41C and the collector electrode 42C of the first transistor 41 in addition to the function of joining the support substrate 20 and the element forming layer 202 (such as FIG. 4A) to each other.

Next, other excellent effects of the semiconductor device according to the first example will be described.

At a mid-production stage of the semiconductor device according to the first example (FIG. 3B), electrodes connected to the emitter line 44E, the collector line 44C, and the base line 44B (FIG. 1) of the second layer are exposed to the surface of the element forming layer 202. Accordingly, before the element forming layer 202 is joined to the support substrate 20, an evaluation test of the first transistor 41 can be performed by bringing probes into contact with these electrodes.

In addition, in the semiconductor device (FIG. 2) according to the first example, the heat generated by the first transistor 41 is conducted to the support substrate 20 via the bonding layer 21 and is also conducted to the module substrate on which the semiconductor device is mounted, via the emitter lines 43E and 44E, the emitter protrusion electrode 83E, and the like. Since the heat generated by the first transistor 41 is conducted in two (up and down) directions, the heat dissipation from the first transistor 41 can be improved. To improve the heat dissipation, it is preferable to use, as the material of the support substrate 20, a material having a higher thermal conductivity than the semiconductor materials that constitutes the collector layer 41C, the base layer 41B, and the emitter layer 41E of the first transistor 41 and the semiconductor material that constitutes the sub-collector region 40A. In the first example, the thermal conductivity of Si, which is the material of the support substrate 20, is higher than the thermal conductivity of GaAs, which is the material of the collector layer 41C, the base layer 41B, and the sub-collector region 40A and the thermal conductivity of InGaP, which is the material of the emitter layer 41E, and the like. Accordingly, the effects large enough to improve the heat dissipation from the first transistor 41 can be obtained.

### Second Example

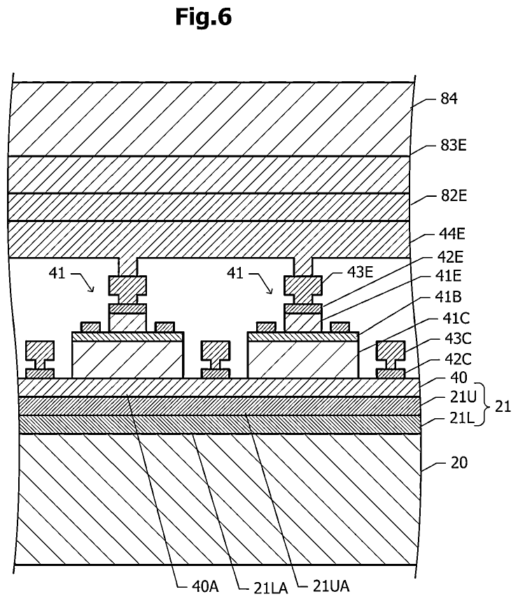

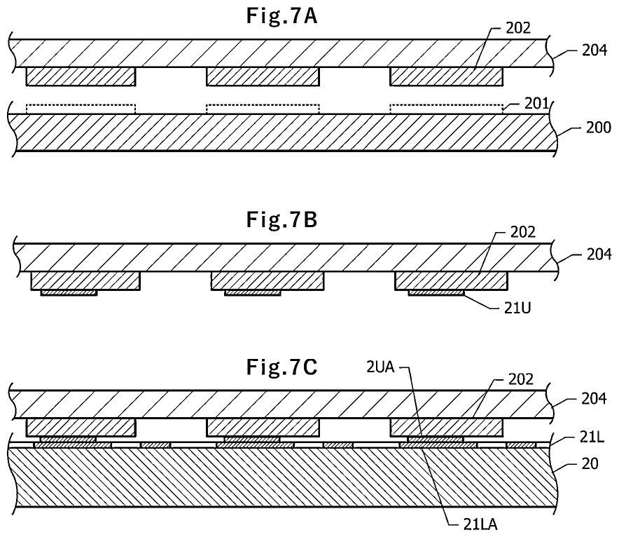

Next, a semiconductor device according to a second example will be described with reference to FIGS. 6 to 7C. The structure common to that of the semiconductor device according to the first example, which has been described with reference to FIGS. 1 to 5, will not be described below.

FIG. 6 is a cross-sectional view of the semiconductor device according to the second example. In the semiconductor device according to the first example (FIG. 1), the bonding layer 21 includes at least one metal region 21A of a single layer. On the other hand, in the semiconductor device according to the second example, the bonding layer 21 includes two layers: a lower bonding layer 21L closer to the support substrate 20 and an upper bonding layer 21U closer to the underlying layer 40.

The lower bonding layer 21L includes at least one metal region 21LA, and the upper bonding layer 21U includes at least one metal region 21UA. The metal region 21LA of the lower bonding layer 21L overlaps the metal region 21UA of the upper bonding layer 21U in plan view, and both regions are adhered to each other. Metals, such as Au, Ag, Pt, Cu, Al, W, Ti, and Ta are used for the metal regions 21LA and 21UA. The same metal or different metals may be used for the metal region 21LA and the metal region 21UA. The sub-collector region 40A of the underlying layer 40 is electrically connected to the metal region 21UA of the upper bonding layer 21U. It should be noted that the structure in which the metal region 21UA of the upper bonding layer 21U is adhered to the metal region 21LA of the lower bonding layer 21L includes the structure in which both regions are in contact with each other without any gap over the entire area and the structure in which a gap is formed between a portion of the metal region 21UA of the upper bonding layer 21U and a portion of the metal region 21LA of the lower bonding layer 21L and both are in contact with each other in other regions.

Next, a method of manufacturing the semiconductor device according to the second example will be described with reference to FIGS. 7A, 7B, and 7C. FIGS. 7A, 7B, and 7C are cross-sectional views of the semiconductor device according to the second example at mid-production stages. The structure illustrated in FIG. 7A is identical to the structure at a mid-production stage according to the first example illustrated in FIG. 3D. In the first example, the element forming layer 202 is joined to the support substrate 20 with the element forming layer 202 in close contact with the metal region 21A (FIG. 3F) of the bonding layer 21. On the other hand, in the second example, the upper bonding layer 21U is formed on the surface (the lower surface of the underlying layer 40 in FIG. 6) of the element forming layer 202 as illustrated in FIG. 7B.

The upper bonding layer 21U can be formed by depositing a metal film by, for example, a vacuum deposition method or a sputtering method and then removing unnecessary portions by etching. Alternatively, a lift-off method may also be used.

As illustrated in FIG. 7C, the lower bonding layer 21L is formed on the support substrate 20. The lower bonding layer 21L can be formed in the same manner as the method described with reference to FIG. 3E in the first example. The metal region 21LA of the lower bonding layer 21L and the metal region 21UA of the upper bonding layer 21U are joined to each other with the metal region 21UA in close contact with the metal region 21LA. The subsequent steps are the same as those described with reference to FIGS. 4A to 4D in the first example.

Next, excellent effects of the second example will be described.

In the second example, as illustrated in FIG. 7C, the element forming layer 202 is joined to the support substrate 20 with metals in contact with each other. Accordingly, the joint process is easier than the process of joining a metal to a semiconductor with both in contact with each other.

In addition, since the upper bonding layer 21U illustrated in FIG. 7B can be formed in a clean environment, such as a vacuum chamber, the interface between the underlying layer 40 (FIG. 6) and the upper bonding layer 21U (FIG. 6) can be kept in a clean state. As a result, the contact resistance between the sub-collector region 40A of the underlying layer 40 and the metal region 21UA of the upper bonding layer 21U can be reduced. Accordingly, the resistance component R2 connected in parallel to the parasitic resistance R1 (FIG. 5) of the sub-collector region 40A can be further reduced. This can enhance the effect of reducing the parasitic resistance between the collector layer 41C and the collector electrode 42C.

### Third Example

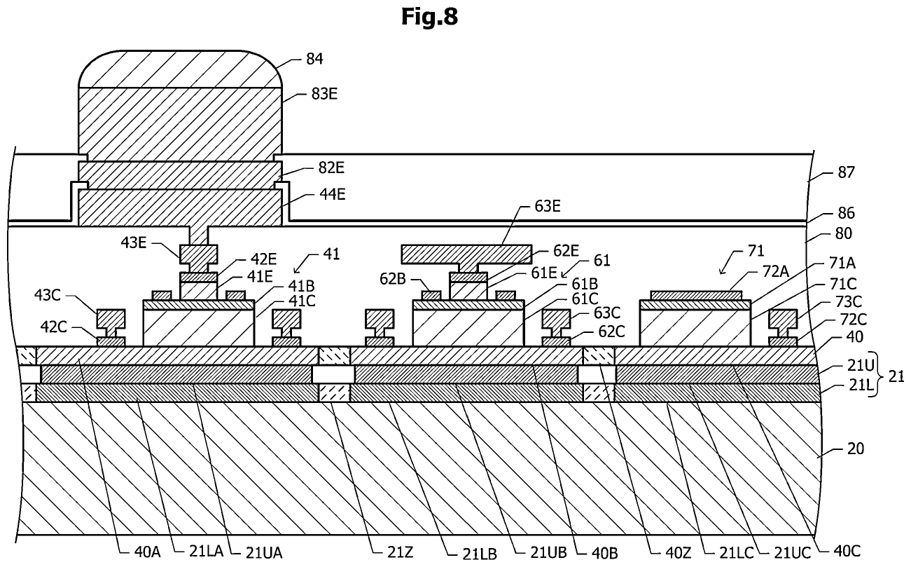

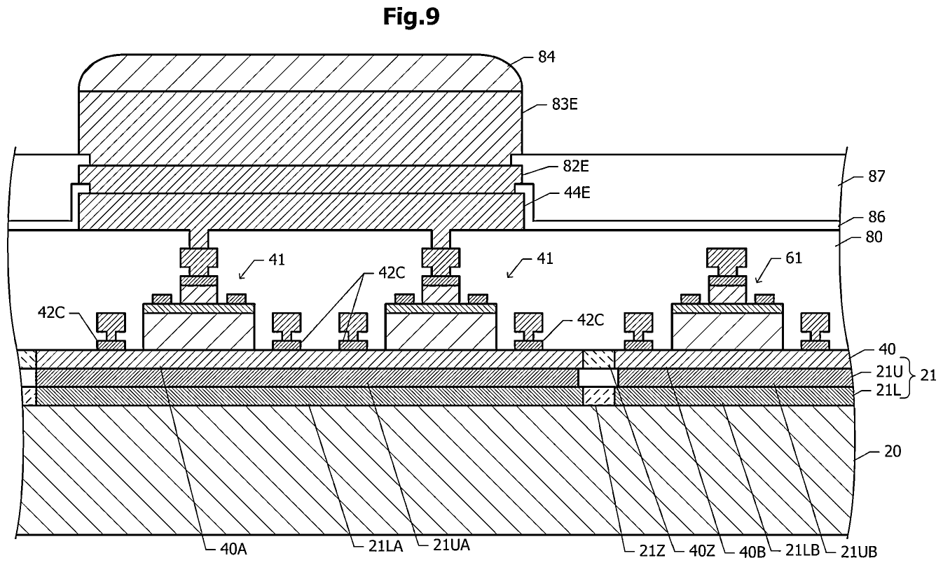

Next, a semiconductor device according to a third example will be described with reference to FIGS. 8 and 9. The structure common to that of the semiconductor device according to the first example, which has been described with reference to FIGS. 1 to 5, will not be described below.

FIGS. 8 and 9 are schematic diagrams illustrating cross-sectional structures of the semiconductor device according to the third example. It should be noted that FIGS. 8 and 9 do not illustrate cross sections of the semiconductor device taken in a specific plane but schematically illustrate structures in the lamination direction and in the in-plane direction. In the first example, the plurality of first transistors 41 are disposed on the underlying layer 40. On the other hand, in the third example, a second transistor 61 and a diode 71 in addition to the plurality of first transistors 41 are disposed on the underlying layer 40. FIG. 8 illustrates one first transistor and FIG. 9 illustrates two first transistors 41, but three or more first transistor 41 may be provided.

In the first example, one collector electrode 42C (FIG. 2) is disposed between two first transistors 41, and one collector electrode 42C is shared by the first transistors 41 on both sides. In the third example, as illustrated in FIG. 9, two collector electrodes 42C are disposed between two first transistors 41. That is, two collector electrodes 42C are disposed for each of the first transistors 41.

As in the second example (FIG. 6), the bonding layer 21 has a two-layer structure including the lower bonding layer 21L and the upper bonding layer 21U. The lower bonding layer 21L includes metal regions 21 LB and 21LC in addition to the metal region 21LA. The metal regions 21LA, 21 LB, and 21LC are electrically isolated from each other by the insulating regions 21Z. The upper bonding layer 21U includes metal regions 21UB and 21UC in addition to the metal region 21UA. The metal regions 21UA, 21UB, and 21UC are separated from each other in the in-plane direction via voids. It should be noted that the plurality of metal regions 21LA, 21 LB, and 21LC of the lower bonding layer 21L may also be separated from each other via voids. In addition, the plurality of metal regions 21UA, 21UB, and 21UC of the upper bonding layer 21U may be electrically isolated from each other via insulating regions.

The underlying layer 40 includes a sub-collector region 40B and a conductive region 40C in addition to the sub-collector region 40A. The sub-collector regions 40A and 40B and the conductive region 40C are isolated from each other via an element isolation region 40Z. The element isolation region 40Z is formed by, for example, performing ion implantation in the underlying layer 40 made of n-type GaAs to increase the resistance.

The sub-collector region 40A and the metal regions 21UA and 21LA overlap each other in plan view and are electrically connected to each other. Similarly, the sub-collector region 40B and the metal regions 21UB and 21 LB also overlap each other in plan view and are electrically connected to each other, and the conductive region 40C and the metal regions 21UC and 21LC also overlap each other in plan view and are electrically connected to each other. Here, “components A, B, and C overlap each other” means that at least a portion of component A, at least a portion of component B, and at least a portion of component C overlap each other in plan view. When one component is contained in another component in plan view, even if the outer edges of two components coincide with each other, it can be said that the two components overlap each other.

Like the first transistor 41, the second transistor 61 is disposed on the sub-collector region 40B and includes a collector layer 61C, a base layer 61B, and an emitter layer 61E. A collector electrode 62C disposed on the sub-collector region 40B is electrically connected to the collector layer 61C via the sub-collector region 40B. A base electrode 62B is connected to the base layer 61B, and an emitter electrode 62E is connected to the emitter layer 61E. A collector line 63C of the first layer is connected to a collector electrode 62C, and an emitter line 63E of the first layer is connected to the emitter electrode 62E. The emitter electrode 62E of the second transistor 61 is not connected to the protruding electrode.

The diode 71 is disposed on the conductive region 40C and includes a cathode layer 71C made of n-type GaAs and an anode layer 71A made of p-type GaAs. The collector layer 41C of the first transistor 41, the collector layer 61C of the second transistor 61, and the cathode layer 71C of the diode 71 are formed by patterning a common n-type GaAs layer. The base layer 41B of the first transistor 41, the base layer 61B of the second transistor 61, and the anode layer 71A of the diode 71 are formed by patterning a common p-type GaAs layer. The emitter layer 41E of the first transistor 41 and the emitter layer 61E of the second transistor 61 are formed by patterning a common n-type InGaP layer or the like.

A cathode electrode 72C is disposed on the conductive region 40C, and the cathode electrode 72C is electrically connected to the cathode layer 71C via the conductive region 40C. A cathode line 73C of the first layer is disposed on the cathode electrode 72C. An anode electrode 72A is disposed on the anode layer 71A. The anode electrode 72A is electrically connected to the anode layer 71A.

An interlayer insulating film 80 is disposed to cover the first transistor 41, the second transistor 61, the diode 71, the emitter lines 43E and 63E, the collector lines 43C and 63C, and the cathode line 73C of the first layer. It should be noted that, an interlayer insulating film is also disposed, for example, between the emitter electrode 42E and the emitter line 43E of the first layer, but this interlayer insulating film is not illustrated. The emitter line 44E of the second layer is disposed on the interlayer insulating film 80. The emitter line 44E of the second layer is connected to the emitter line 43E of the first layer through a cavity provided in the interlayer insulating film 80. The element structure from the underlying layer 40 to the emitter line 44E of the second layer corresponds to the element forming layer 202 (FIG. 7A).

The interlayer insulating film 86 is disposed on the emitter line 44E of the second layer and the interlayer insulating film 80, and a cavity through which the emitter line 44E of the second layer is exposed is provided in the interlayer insulating film 86. As illustrated in FIG. 4B, the interlayer insulating film 86 extends to cover the support substrate 20 outside the element forming layer 202 in plan view.

The emitter pad 82E is disposed on the emitter line 44E of the second layer in a cavity provided in the interlayer insulating film 86 and on the interlayer insulating film 86 around the cavity. The protective film 87 is disposed on the emitter pad 82E and the interlayer insulating film 86, and a cavity through which the emitter pad 82E is exposed is provided in the protective film 87.

The emitter protrusion electrode 83E is disposed on the emitter pad 82E in the cavity of the protective film 87 and on the protective film 87 around the cavity. The solder 84 is placed on the emitter protrusion electrode 83E.

Next, excellent effects of the third example will be described.

In the third example, the plurality of metal regions 21LA, 21 LB, and 21LC of the lower bonding layer 21L are electrically isolated from each other, and the plurality of metal regions 21UA, 21UB, and 21UC of the upper bonding layer 21U are also electrically isolated from each other. Accordingly, these metal regions 21UA, 21UB, 21UC, 21LA, 21 LB, and 21LC of the bonding layer 21 can be used, for each of elements disposed on the underlying layer 40, as low resistance layers that reduce parasitic resistance. For example, the parasitic resistance between the collector layer 61C and the collector electrode 62C of the second transistor 61 in addition to the first transistor 41 can be reduced. Furthermore, the parasitic resistance between the cathode layer 71C of the diode 71 and the cathode electrode 72C can be reduced.

### Fourth Example

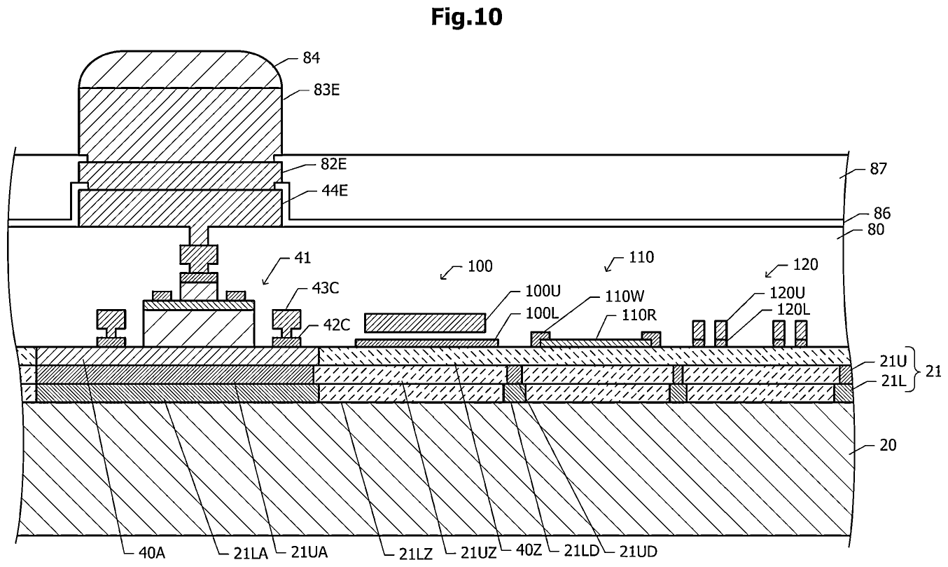

Next, a semiconductor device according to a fourth example will be described with reference to FIG. 10. The structure common to that of the semiconductor device according to the first example, which has been described with reference to FIGS. 1 to 5, will not be described below.

FIG. 10 is a diagram schematically illustrating a cross-sectional structure of the semiconductor device according to the fourth example. In the fourth example, a capacitor 100, a resistance element 110, and an inductor 120 in addition to the first transistor 41 are disposed. The capacitor 100, the resistance element 110, and the inductor 120 are disposed on the element isolation region 40Z of the underlying layer 40.

The capacitor 100 includes a lower electrode 100L and an upper electrode 100U disposed thereon via an interlayer insulating film. The resistance element 110 includes a high-resistance portion 110R and end connection lines 110W connected to both ends thereof. The inductor 120 includes a spiral line having a two-layer structure including a lower layer 120L and an upper layer 120U. The lower electrode 100L of the capacitor 100, the end connection line 110W of the resistance element 110, and the lower layer 120L of the inductor 120 are formed by, for example, patterning a metal film that is the same as that of the collector electrode 42C. The upper electrode 100U of the capacitor 100 and the upper layer 120U of the inductor 120 are formed by patterning a metal film that is the same as that of the collector line 43C of the first layer.

The lower bonding layer 21L includes a plurality of metal regions 21LD and an insulating region 21LZ in addition to the metal region 21LA. The insulating region 21LZ is formed by a damascene method like the insulating regions 21Z formed in, for example, the step illustrated in FIG. 3E in the first example. It should be noted that the insulating region 21LZ may be a natural oxide film formed on the surface of the support substrate 20 made of Si.

The upper bonding layer 21U includes a plurality of metal regions 21UD and an insulating region 21UZ in addition to the metal region 21UA. The metal region 21LA of the lower bonding layer 21L and the metal region 21UD of the upper bonding layer 21U overlap each other in plan view, and both regions are in close contact with each other. The capacitor 100, the resistance element 110, and the inductor 120 are contained in the insulating region 21LZ and the insulating region 21UZ in plan view.

As an example, the plurality of first transistors 41 constitute a high-frequency amplification circuit. The capacitor 100 is a DC cut capacitor that eliminates DC components from a high-frequency signal, and the resistance element 110 is a base ballast resistance element. In addition, the capacitor 100 and the inductor 120 may constitute an impedance matching circuit.

Next, excellent effects of the fourth example will be described.

In the fourth example, since various passive elements in addition to the plurality of first transistors 41 are disposed on the underlying layer 40, the electronic circuit can be miniaturized as compared with a structure in which the passive elements are disposed externally. Since the plurality of passive elements are contained in the insulating regions 21UZ and 21LZ and do not overlap the metal regions 21UD and 21LD in plan view, the parasitic capacitances between the passive elements and the metal regions 21UD and 21LD can be reduced. Accordingly, instability of operation due to high-frequency coupling between the first transistor 41 and the passive element can be avoided.

### Fifth Example

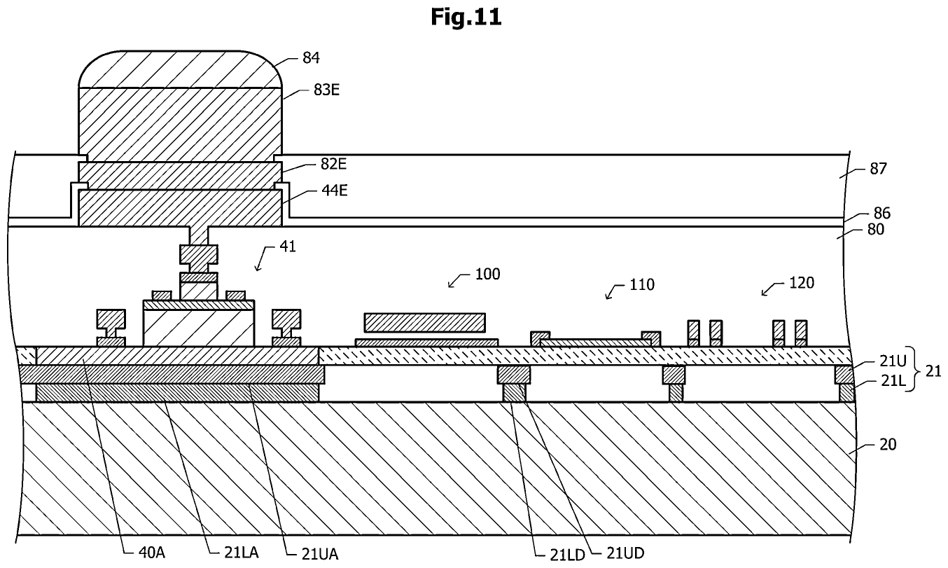

Next, a semiconductor device according to a fifth example will be described with reference to FIG. 11. The structure common to that of the semiconductor device according to the fourth example, which has been described with reference to FIG. 10, will not be described below. FIG. 11 is a diagram schematically illustrating a cross-sectional structure of the semiconductor device according to the fifth example.

In the fourth example (FIG. 10), the metal regions 21LA and 21LD of the lower bonding layer 21L are electrically isolated from each other by the insulating region 21LZ, and the metal regions 21UA and 21UD of the upper bonding layer 21U are electrically isolated from each other by the insulating region 21UZ. On the other hand, in the fifth example, there is a void between the metal regions 21LA and 21LD of the lower bonding layer 21L, and there is also a void between the metal regions 21UA and 21UD of the upper bonding layer 21U. For example, in the step illustrated in FIG. 3E in the first example, the metal regions 21LA and 21LD separated by voids are formed by forming and patterning a metal film on the support substrate 20. The capacitor 100, the resistance element 110, and the inductor 120 are contained in the voids of the lower bonding layer 21L and upper bonding layer 21U in plan view.

Next, excellent effects of the fifth example will be described.

Also in the fifth example, as in the fourth example (FIG. 10), the electronic circuit can be miniaturized and instability of operation due to high-frequency coupling between the first transistor 41 and the passive elements can be avoided.

### Sixth Example

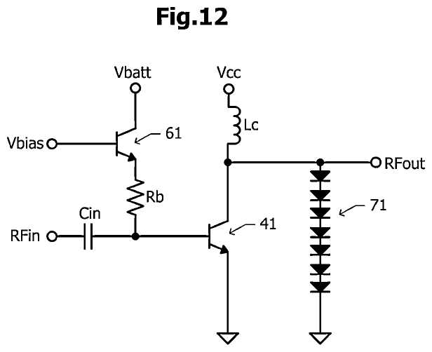

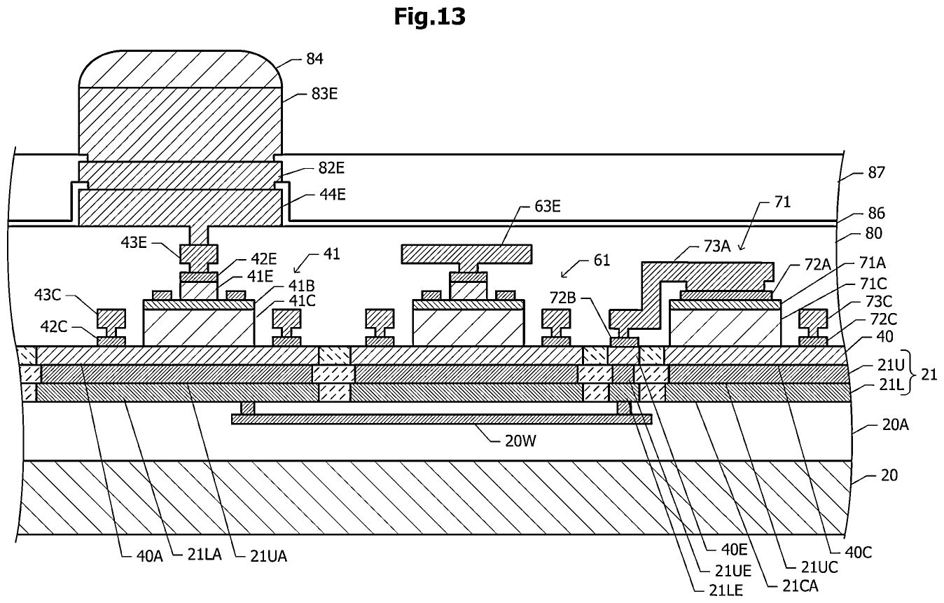

Next, a semiconductor device according to a sixth example will be described with reference to FIGS. 12 and 13. The structure common to that of the semiconductor device according to the third example, which has been described with reference to FIGS. 8 and 9, will not be described below.

FIG. 12 is an equivalent circuit diagram of the semiconductor device according to the sixth example. The first transistor 41 constitutes a power amplification circuit. A power supply voltage Vcc is applied to the collector of the first transistor 41 through a choke coil Lc, and the emitter of the first transistor 41 is grounded.

A base bias circuit of the first transistor 41 includes the second transistor 61. The emitter of the second transistor 61 is connected to the base of the first transistor 41 via a base ballast resistor Rb. A battery voltage Vbatt is applied to the collector of the second transistor 61, and a bias control signal Vbias is supplied to the base of the second transistor 61. A base bias is supplied to the base of the first transistor 41 via the second transistor 61 and the base ballast resistor Rb. A high-frequency signal RFin is input to the base of the first transistor 41 through the input capacitor Cin. An output signal RFout is output from the collector of the first transistor 41.

The collector of the first transistor 41 is grounded via the plurality of diodes 71 connected in series. The plurality of diodes 71 are connected with polarity in a forward direction from the collector of the first transistor 41 to the ground potential and serve as clamp diodes.

FIG. 13 is a diagram schematically illustrating a cross-sectional structure of the semiconductor device according to the sixth example. In the third embodiment (FIGS. 8 and 9), the lower bonding layer 21L is in direct contact with the silicon surface of the support substrate 20. On the other hand, in the sixth example, the support substrate 20 includes a multi-layer wiring layer 20A in a surface layer portion, and the lower bonding layer 21L is in contact with a surface of the multi-layer wiring layer 20A.

The underlying layer 40 includes a conductive region 40E, the upper bonding layer 21U includes a metal region 21UE, and the lower bonding layer 21L includes a metal region 21LE. A connection electrode 72B is disposed on the conductive region 40E. The conductive region 40E and the metal regions 21UE and 21LE overlap each other in plan view and are electrically connected to each other. The anode electrode 72A of the diode 71 is connected to a connection electrode 72B via an anode line 73A of the first layer.

A line 20W included in the multi-layer wiring layer 20A connects the metal region 21LA and the metal region 21LE to each other. That is, the collector layer 41C of the first transistor 41 is electrically connected to the anode layer 71A of the diode 71 via the line 20W in the multi-layer wiring layer 20A. The collector line 43C and the collector electrode 42C electrically connected to the collector layer 41C of the first transistor 41 are used as electrodes to which probes for an evaluation test are connected, at the stage illustrated in FIG. 3B of the first example.

Next, excellent effects of the sixth example will be described.

In the sixth example, the line 20W in the multi-layer wiring layer 20A of the support substrate 20 connects the first transistor 41 and the diode 71 to each other. As a result, the degree of freedom in the disposition of lines on the underlying layer 40 can be improved. In addition, by using the collector line 43C connected to the sub-collector region 40A and the collector line 44C (FIG. 1) thereon as electrodes for an evaluation test, an evaluation test can be performed with the underlying layer 40 not joined to the support substrate 20 (FIG. 3B). The metal region 21LA of the lower bonding layer 21L and the metal region 21UA of the upper bonding layer 21U have the function of reducing the parasitic resistance between the collector electrode 42C and the collector layer 41C by flowing current in the in-plane direction, and the function of connecting the collector layer 41C and the line 20W in the support substrate 20 to each other by flowing current in the thickness direction.

The examples described above are only examples, and it will be appreciated that a partial substitution or combination of structures illustrated in different examples are possible. The same operation and effect of the same structure between a plurality of examples will not be described for each example. In addition, the present disclosure is not limited to the examples described above. For example, it is obvious to those skilled in the art that various modifications, improvements, combinations, and the like are possible.

What is claimed is:

1. A semiconductor device comprising:
a support substrate;
a bonding layer including a first metal region on at least a portion of an upper surface of the support substrate;
an underlying layer on the bonding layer, the underlying layer including a sub-collector region including a conductive semiconductor material and electrically connected to the first metal region;
a first transistor on the sub-collector region, the first transistor including a collector layer electrically connected to the sub-collector region, a base layer on the collector layer, and an emitter layer on the base layer; and
a collector electrode on the sub-collector region, the collector electrode being outward of the first transistor to overlap the first metal region in plan view, and the collector electrode being electrically connected to the sub-collector region.

2. The semiconductor device according to claim 1, wherein
the first metal region includes at least one metal selected from the group consisting of Au, Ag, Pt, Cu, Al, W, Ti, and Ta.

3. The semiconductor device according to claim 1, wherein
the first metal region includes a first lower metal region closer to the support substrate and a first upper metal region closer to the underlying layer, and the first lower metal region and the first upper metal region are adhered to each other.

4. The semiconductor device according to claim 1, wherein
the support substrate includes a semiconductor material having a thermal conductivity higher than a thermal conductivity of a semiconductor material that configures the collector layer, the base layer, and the emitter layer of the first transistor and a thermal conductivity of the semiconductor material that configures the sub-collector region.

5. The semiconductor device according to claim 1, wherein
the bonding layer further includes at least one second metal region electrically isolated from the first metal region.

6. The semiconductor device according to claim 5, wherein
the underlying layer further includes an insulating element isolation region outward of the sub-collector region in plan view, and
the semiconductor device further comprises:
a passive element on an element isolation region and not overlapping the first metal region or the second metal region in plan view.

7. The semiconductor device according to claim 5, further comprising:
an insulating region between the first metal region and the second metal region in plan view, the insulating region including an oxide or a nitride.

8. The semiconductor device according to claim 5, wherein
a void is between the first metal region and the second metal region in plan view.

9. The semiconductor device according to claim 2, wherein
the first metal region includes a first lower metal region closer to the support substrate and a first upper metal region closer to the underlying layer, and the first lower metal region and the first upper metal region are adhered to each other.

10. The semiconductor device according to claim 2, wherein
the support substrate includes a semiconductor material having a thermal conductivity higher than a thermal conductivity of a semiconductor material that configures the collector layer, the base layer, and the emitter layer of the first transistor and a thermal conductivity of the semiconductor material that configures the sub-collector region.

11. The semiconductor device according to claim 3, wherein
the support substrate includes a semiconductor material having a thermal conductivity higher than a thermal conductivity of a semiconductor material that configures the collector layer, the base layer, and the emitter layer of the first transistor and a thermal conductivity of the semiconductor material that configures the sub-collector region.

12. The semiconductor device according to claim 9, wherein
the support substrate includes a semiconductor material having a thermal conductivity higher than a thermal conductivity of a semiconductor material that configures the collector layer, the base layer, and the emitter layer of the first transistor and a thermal conductivity of the semiconductor material that configures the sub-collector region.

13. The semiconductor device according to claim 2, wherein
the bonding layer further includes at least one second metal region electrically isolated from the first metal region.

14. The semiconductor device according to claim 3, wherein
the bonding layer further includes at least one second metal region electrically isolated from the first metal region.

15. The semiconductor device according to claim 4, wherein
the bonding layer further includes at least one second metal region electrically isolated from the first metal region.

16. The semiconductor device according to claim 13, wherein
the underlying layer further includes an insulating element isolation region outward of the sub-collector region in plan view, and
the semiconductor device further comprises:
a passive element on an element isolation region and not overlapping the first metal region or the second metal region in plan view.

17. The semiconductor device according to claim 14, wherein
the underlying layer further includes an insulating element isolation region outward of the sub-collector region in plan view, and
the semiconductor device further comprises:
a passive element on an element isolation region and not overlapping the first metal region or the second metal region in plan view.

18. The semiconductor device according to claim 15, wherein
the underlying layer further includes an insulating element isolation region outward of the sub-collector region in plan view, and
the semiconductor device further comprises:
a passive element on an element isolation region and not overlapping the first metal region or the second metal region in plan view.

19. The semiconductor device according to claim 6, further comprising:
an insulating region between the first metal region and the second metal region in plan view, the insulating region including an oxide or a nitride.

20. The semiconductor device according to claim 6, wherein
a void is between the first metal region and the second metal region in plan view.
